(19) United States
(12) Patent Application Publication
(10) Pub. No.: US 2026/0298747 A1
(43) Pub. Date: Oct. 1, 2026

(54) ELECTRICAL CONNECTION TO PROCESS FLUID PRESSURE SENSOR

(71) Applicant: Rosemount Inc., Shakopee, MN (US)

(72) Inventors: Tyler John Ludwigson, Brenham, TX (US); Christopher L. Eriksen, St. Paul, MN (US)

(21) Appl. No.: 19/090,988

(22) Filed: Mar. 26, 2025

(51) Int. Cl. G01L 9/00

(52) U.S. Cl. CPC G01L 9/0072

(57) ABSTRACT

A process variable transmitter configured to sense a process pressure of a process fluid in an industrial process. The transmitter includes a pressure sensor and measurement circuitry carried on a circuit board electrically couples to the pressure sensor and measures the process pressure. At least one via hole is formed in the printed circuit board which is electrically coupled to the measurement circuitry. A slot extends from the via hole to an edge of the circuit board. A wire is soldered to the via hole and electrically connects the via hole to an electrical connection on the pressure sensor to thereby complete an electrical connection between the pressure sensor and the measurement circuitry. A method is also provided.

### BACKGROUND

The present invention relates to pressure transmitters used in industrial processes for monitoring a process fluid pressure. More specifically, the invention relates to electrically connecting to a pressure sensor in such a device.

A process transmitter generally includes a transducer or sensor that responds to a process variable. A process variable generally refers to a chemical or physical state of matter or conversion of energy. Examples of process variables include pressure, temperature, flow, conductivity, pH, and other properties. Pressure is considered to be a basic process variable in that it can be used to measure flow, level, and even temperature.

Pressure transmitters are commonly used in industrial processes to measure and monitor pressures of various industrial process fluids, such as slurries, liquids, vapors, and gases of chemical, pulp, petroleum, gas, pharmaceuticals, food, and other fluid-type processing plants. Differential pressure transmitters generally include a pair of process pressure fluid inputs which are operably coupled to a differential pressure sensor (within the transmitter) that responds to the difference in pressure between the two inputs. Differential pressure transmitters typically include a differential pressure sensor operably coupled to a pair of isolator diaphragms. The isolator diaphragms are positioned at the process fluid inlets and isolate the differential pressure sensor from the harsh process fluids being sensed. Pressure is transferred from the process fluid to the differential pressure sensor through a substantially incompressible fill fluid carried in a passageway extending from the isolator diaphragm to the differential pressure sensor.

A process fluid pressure transmitter is generally considered a field device and it is able to be mounted in the field. “Field” is generally an external area in a process installation that may be subject to climatological extremes, vibration, changes in humidity, electromagnetic or radio frequency interface, or other environmental challenges. Thus, the robust physical package of a process fluid pressure transmitter provides the transmitter with the ability to operate in the “field” for extended periods (such as years) at a time.

### SUMMARY

A process variable transmitter configured to sense a process pressure of a process fluid in an industrial process. The transmitter includes a housing and a pressure sensor configured to sense an applied pressure. The pressure sensor has an electrical characteristic which changes in response to the applied pressure. Measurement circuitry carried on a circuit board electrically couples to the pressure sensor and measures the process pressure based upon changes in the electrical characteristic of the pressure sensor. At least one via hole is formed in the printed circuit board which is electrically coupled to the measurement circuitry. A slot extends from the via hole to an edge of the circuit board. A wire is soldered to the via hole and electrically connects the via hole to an electrical connection on the pressure sensor to thereby complete an electrical connection between the pressure sensor and the measurement circuitry for use in sensing the electrical parameter of the pressure sensor by the measurement circuitry. A method is also provided.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. The claimed subject matter is not limited to implementations that solve any or all disadvantages noted in the Background.

### BRIEF DESCRIPTION OF THE DRAWINGS

FIG. 1 illustrates a front view of an exemplary pressure transmitter.

FIG. 2 illustrates an oblique sectional view of a module housing of the transmitter of FIG. 1 which includes a pressure sensor and measurement circuitry.

FIG. 3 is a cross-sectional view of the sensor module of FIG. 2 showing wires which connect the pressure sensor to measurement circuity carried on a circuit board.

FIG. 4 is a perspective view of a prior art configuration in which connecting wires are routed through vias in a circuit board.

FIG. 5 is a perspective view of a prior art configuration in which connecting wires are routed around an edge of a circuit board and wire wrapped onto posts of the circuit board.

FIG. 6 is a plan view of a circuit board in which slots are used for placing connecting wires in via holes in a circuit board.

FIG. 7 is a close up perspective view of a slot and via hole in the circuit board in FIG. 6.

FIG. 8 is a perspective view of a circuit board positioned in a sensor module which utilizes slots for placement of wires in via holes.

FIG. 9 is a close up perspective view of another example embodiment of a slot having an angle for use for placing a wire in a via hole.

FIG. 10 is a close up perspective view of another example embodiment of a slot having a spiral for use for placing a wire in a via hole.

FIG. 11 is a close up perspective view of another example embodiment of a slot having a taper for use for placing a wire in a via hole.

### DETAILED DESCRIPTION OF ILLUSTRATIVE EMBODIMENTS

As discussed in the Background section, a process variable transmitter must operate in harsh environmental condition without failure. Components within the transmitter must be sealed from the external environment, and be able to withstand extreme conditions including vibration, physical shocks, and temperature extremes. The electrical components within the device must maintain their electrical connections even when subject to these conditions. In the current pressure transmitter configurations such as the Rosemount Inc., 3051C and 3051S_C, making electrical connections from the pressure sensor to the circuit board that carries measurement circuitry can be challenging. Blind through-hole connections (“vias”) are used to connect the lead wires from the pressure sensor to the measurement circuitry. This arrangement provides a robust electrical connection. However, this is only viable for small numbers of interconnects and must be assembled by hand. In another configuration, wire-wrapped posts are used for electrical connection. This configuration allows higher wire densities but requires significant assembly precision to make the electrical connection without creating weak points in the lead wires or compromising the strain reliefs.

In one aspect, this invention provides a new tapered slot geometry that can be implemented to make higher density connections from the pressure sensor to the circuitry board which carries the measurement circuitry. This facilitates robust, reliable connections that can be made in an automated assembly process and allows the pressure transmitter to achieve a higher vibration rating than the prior art configuration.

Embodiments of the present disclosure are described more fully hereinafter with reference to the accompanying drawings. Elements that are identified using the same or similar reference characters refer to the same or similar elements. Some elements may not be shown in each of the figures in order to simplify the illustrations.

The various embodiments of the present disclosure may be embodied in many different forms and should not be construed as limited to the specific embodiments set forth herein. Rather, these embodiments are provided so that this disclosure will be thorough and complete, and will fully convey the scope of the present disclosure to those skilled in the art.

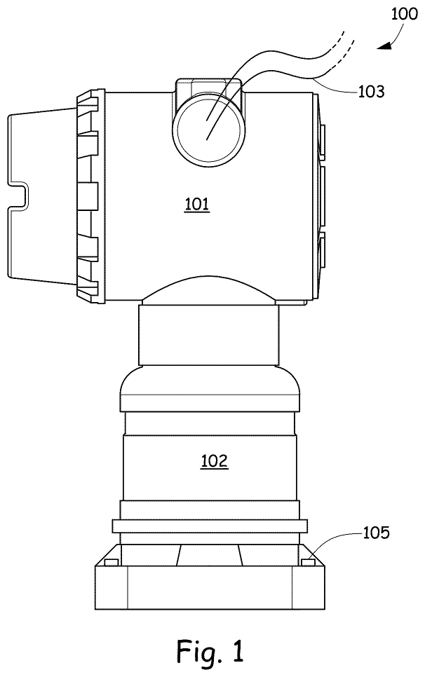

FIG. 1 illustrates a front view of an exemplary a process fluid pressure transmitter 100. Pressure transmitter 100 includes an electronics housing 101 that encloses electronic circuitry and a pressure sensor module housing 102 that houses isolator diaphragms, a pressure sensor and associated sensor measurement circuitry. Pressure sensor module housing 102 is bolted to a pressure flange (not shown) by bolts 105. The pressure flange provides one or more process fluids pressures to the transmitter 100 for pressure measurement. Pressure transmitter 100 is connected to process control loop 103 that energizes pressure transmitter 100 and provides bidirectional communication for use in a process control system. The process control loop 103 can be in accordance with any appropriate process control communication standard. For example, the loop 103 can carry a 4-20 mA current which carries information as well as provides power to the device. Digital signals may also be communicated on loop 103. In a further embodiment, loop 103 is a wireless embodiment in which the loop provides wireless communication between the process variable transmitter 101 and a remote location such as a control room.

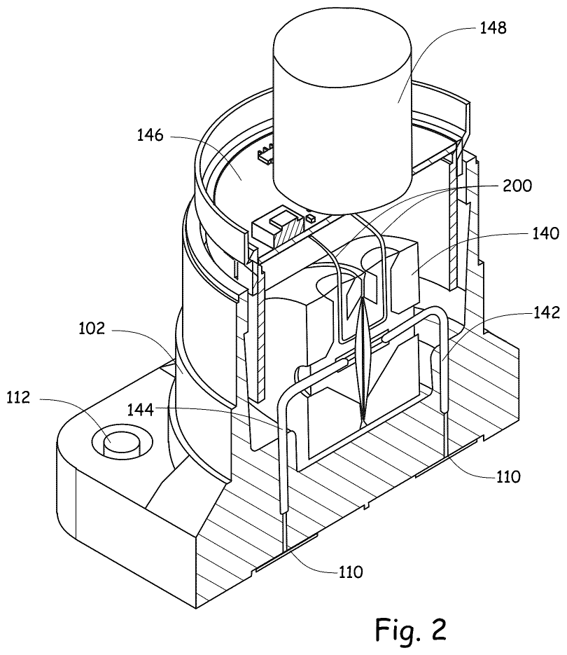

Pressure sensor module housing 102 (in this embodiment measuring differential pressure) includes isolator diaphragms 110 (shown in FIG. 2) that are welded directly to pressure sensor module housing 102. Housing 102 also includes threaded bolt holes 112 in a standard pattern around isolator diaphragms 110.

FIG. 2 illustrates an oblique sectional view of pressure sensor module housing 102. Differential pressure sensor 140 is located inside pressure sensor module housing 102 and connects, by tubes (impulse pipes) 142, 144, to isolator diaphragms 110. Isolator diaphragms 110 are welded directly to pressure sensor module housing 102. In the configuration of FIG. 2, pressure sensor 140 is configured as a capacitive based sensor. A differential pressure is applied to sensor 140 through a fill fluid carried in tubes 142,144 and an internal diaphragm deflects in response to the applied pressures. This causes an electrical capacitance between the internal walls of the sensor 140 and the sensor diaphragm to change as a function of the applied pressure. A circuit board 146 provides measurement circuitry associated with processing electrical signals from differential pressure sensor 140. The differential pressure can be used to measure flow rate of a process fluid through process piping, fill level of process fluid in a storage tank, or other process variables. An optional flat cable reel 148 houses a flat cable that provides electrical connections from circuit board 146 to circuitry in an electronics housing (such as housing 101 shown in FIG. 1). In another configuration, module 102 operates independently and communicates information related to the sensed pressure through, for example, process control loop 103.

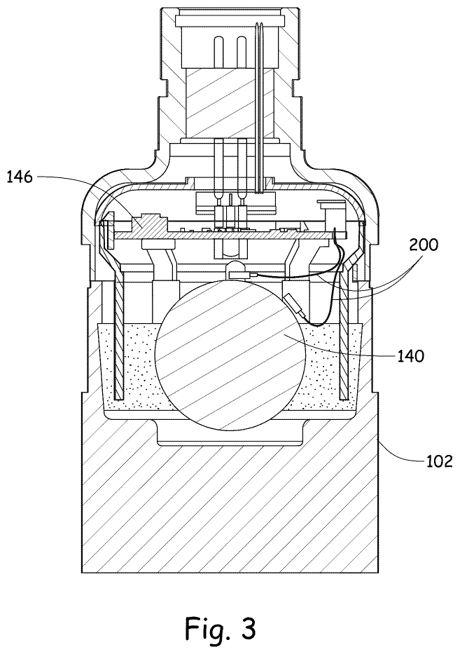

As discussed above, in a pressure transmitter, the lead wires 200 from the pressure sensor 140 are connected to measurement circuitry carried on circuited board 146. This is illustrated in the cross sectional view of sensor module 102 shown in FIG. 3. Some configurations of a coplanar sensor module 102 have between three and five 200 that must be connected to the circuit board 146.

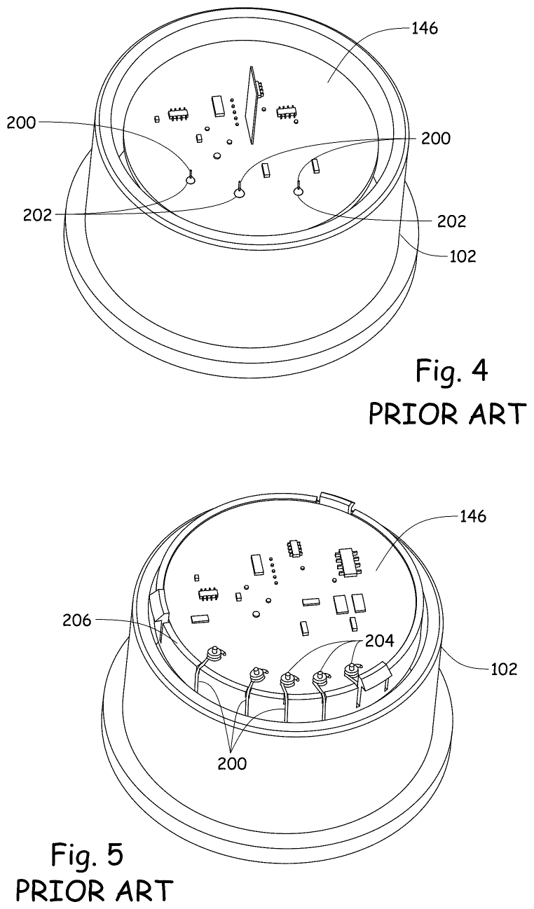

In one prior art configuration illustrated in FIG. 4, three wires 200 are pulled through via holes 202 in the circuit board 146 and soldered in place. The via holes have electrical traces that connect the wires 200 to the measurement circuitry carried on circuit board 146. This configuration provides a robust arrangement which is capable of withstanding the harsh environment common in industrial processes. However, the technique is only viable for a small number of electrical connections. Further, this technique requires hand-assembly of the soldered connection.

Another example prior art configuration uses five wires 200 that are routed around the edge 206 of the board 146. The wires 200 are then manually wrapped around square turrets or posts 204 and soldered in place as shown in perspective view of FIG. 5. The assembly process requires significant operator skill to make these joints without creating weak points in the lead wires 200. Further, a strain relief is preferably carried on wires 200 and is used to protect the wires 200 from forces exerted along the edge 206 of board 146. During the assembly process, care must be taken to ensure that these strain reliefs are not compromised. Additionally, the turrets 204 require a considerable amount of space on the board 146 and are time-consuming to wrap.

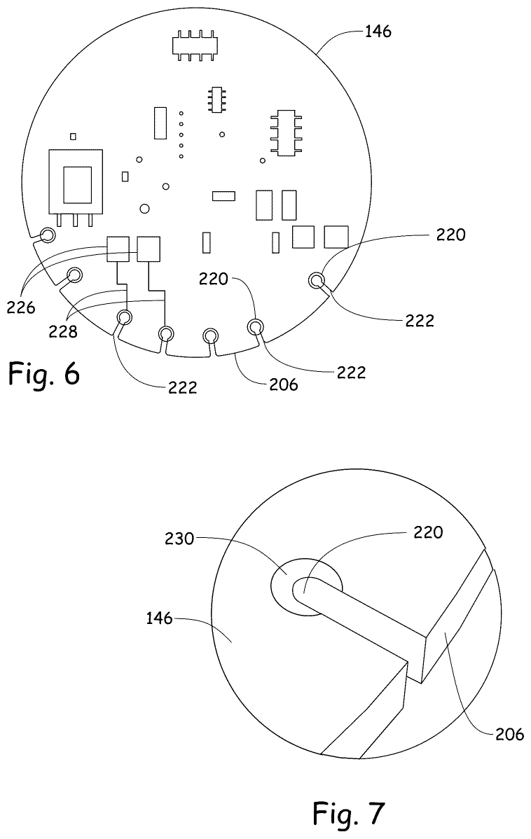

This present invention provides a new lead wire joint geometry in an industrial process pressure transmitter to address the challenges discussed above. One example of this configuration is shown in FIG. 6 which is a plan view of printed circuit board 146. In the plan view shown in FIG. 6, the circuit board 146 includes a number of via holes 220. The via holes 220 couple to a slot 222 which extends from the via hole 220 to the edge 206 of circuit board 146. FIG. 6 also illustrates measurement circuitry 226 carried on circuit board 146. The measurement circuitry 226 is electrically connected to via holes 220 through electrical trace connections 228. In the configuration of FIG. 6 seven via holes 220 and slots 222 are illustrated, however, any number can be used as desired.

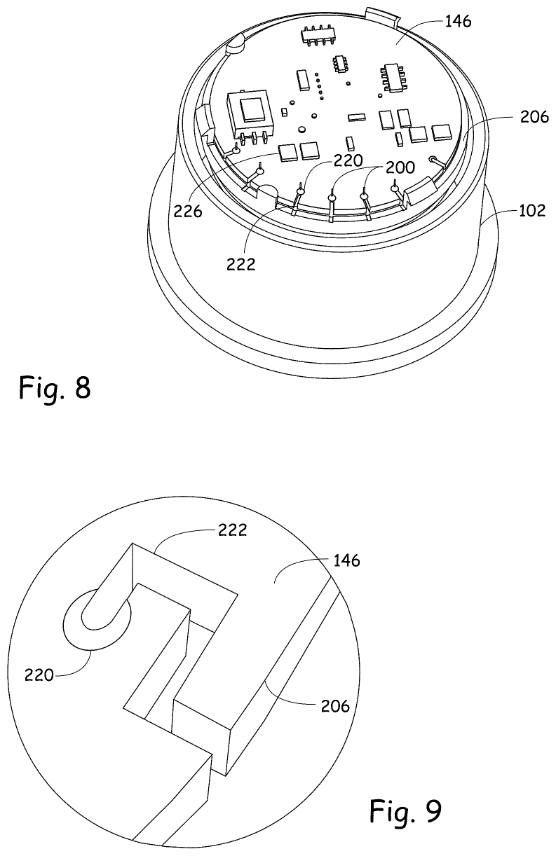

FIG. 7 is an enlarged perspective view of via holes 220 shown in FIG. 5. As illustrated in FIG. 7, via hole 220 is surrounded by a metal pad 230. The opening provided by via hole 220 extends to the edge 206 of printed circuit board 146 by means of slot 222. The metal pad 230 is suitable for providing a solder connection and electrically connects to electrical trace connections 228 shown, for example, in FIG. 6. The wire 200 can be slid into place by sliding it through the slot 222 and into position in the via hole 220. Once the wire 200 is in position, it can be soldered to metal pad 230 to thereby secure the wire within the via hole 220 and provide an electrical connection to measurement circuity 226 through electrical trace connections 228. FIG. 8 is a perspective view of module 102 showing circuit board 146 secured in place with wires 200 soldered to the metal pad 230.

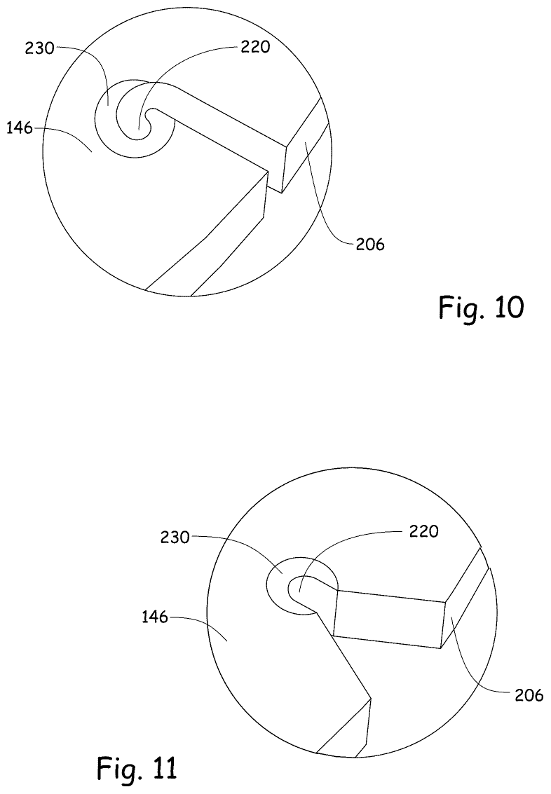

The slotted configuration is well suited for automated assembly in which the wires 200 are automatically placed into the via holes 220 by pulling them through slots 222. An automated soldering station can then be used to solder the wires 200 to the metal pads 230. This configuration provides a robust design which can withstand high levels of G forces and vibrations. In one configuration, the slots 222 have a spiral or angled shape to facilitate placing and/or securing the wires 200 in their correct position during assembly. Such a configuration is illustrated in, for example, the plan view of FIG. 9. In FIG. 9 the configuration of slot 222 includes at least one angle. The act of pulling the wire 200 through the slot 222 causes a spring back force urges the wire 200 toward the edge 206 of the board 146. After moving the wire 200 around the bend in the slot 222, this force will hold the wire 200 in position until it has been soldered in place. FIG. 10 illustrates another example configuration using a spiral slot 220. A tapered slot 220 configuration is illustrated in FIG. 11

In one configuration, the wires 200 a soldered to the circuit board 146 prior to connecting them to sensor 140. Strain relief features can also be provided on wires 200 to improve reliability. A feature can also be provided to assist in guiding the wires 200 into the correct position during assembly.

Although the present invention has been described with reference to preferred embodiments, workers skilled in the art will recognize that changes may be made in form and detail without departing from the spirit and scope of the invention. With this configuration, the wires 200 can be slid into position through the slots 222 and soldered onto the metal pad 230. Subsequent to being soldered, excess wire can be cut so that the wire 200 is substantially flush with the surface of circuit board 146. Although a capacitance based pressure sensor has been described herein, the invention is applicable to any type of pressure sensing technology. Although three and five wires are shown, any number of wires can be used. Although a pressure transmitter is discussed, the invention can be used with any type of process variable transmitter.

What is claimed is:

1. A process variable transmitter configured to sense a process pressure of a process fluid in an industrial process, comprising:
a housing;
a pressure sensor configured to sense an applied pressure and having an electrical characteristic which changes in response to the applied pressure;
measurement circuitry carried on a circuit board configured to electrically couple to the pressure sensor and measure the process pressure based upon changes in the electrical characteristic of the pressure sensor;
at least one via hole formed in the printed circuit board which is electrically coupled to the measurement circuitry;
a slot which extends from the via hole to an edge of the circuit board; and
a wire which is soldered in the via hole and which electrically connects the via hole to an electrical connection on the pressure sensor to thereby complete an electrical connection between the pressure sensor and the measurement circuitry for use in sensing the electrical parameter of the pressure sensor by the measurement circuitry.

2. The process variable transmitter of claim 1 wherein the slot is straight.

3. The process variable transmitter of claim 1 wherein the slot includes at least one angle.

4. The process variable transmitter of claim 1 wherein the slot is tapered.

5. The process variable transmitter of claim 1 including a metal pad which surrounds the via hole and is electrically coupled to the measurement circuity.

6. The process variable transmitter of claim 5 wherein the wire is soldered to the metal pad.

7. The process variable transmitter of claim 1 including a total of three wires soldered to the via hole which connect the pressure sensor to the measurement circuity.

8. The process variable transmitter of claim 1 including a total of five wires soldered to the via hole which connect the pressure sensor to the measurement circuity.

9. The process variable transmitter of claim 1 wherein the process variable transmitter is coupled to a process control loop and information related to sensed pressure is communicated on the process control loop.

10. The process variable transmitter of claim 1 wherein the slot is angled or a spiral.

11. The process variable transmitter of claim 1 wherein the pressure sensor comprises a differential pressure sensor.

12. A method of manufacturing a process variable transmitter configured to sense a process pressure of a process fluid in an industrial process, comprising:
providing a housing;
providing a pressure sensor configured to sense an applied pressure and having an electrical characteristic which changes in response to the applied pressure;
providing measurement circuitry carried on a circuit board configured to electrically couple to the pressure sensor and measure the process pressure based upon changes in the electrical characteristic of the pressure sensor;
forming at least one via hole in the printed circuit board which is electrically coupled to the measurement circuitry;
forming a slot which extends from the via hole to an edge of the circuit board;
sliding a wire through the slot and into the via hole which electrically connects the via hole to an electrical connection on the pressure sensor to thereby complete an electrical connection between the pressure sensor and the measurement circuitry for use in sensing the electrical parameter of the pressure sensor by the measurement circuitry; and
soldering the wire to the via hole.

13. The method of claim 12 wherein the slot is straight.

14. The method of claim 12 wherein the slot includes at least one angle.

15. The method of claim 12 wherein the slot is tapered.

16. The method of claim 12 including providing a metal pad which surrounds the via hole and is electrically coupled to the measurement circuity.

17. The method of claim 16 wherein the wire is soldered to the metal pad.

18. The method of claim 12 including connecting the pressure sensor to the measurement circuity with a total of three wires soldered to the via hole.

19. The method of claim 12 including connecting the pressure sensor to the measurement circuity with a total of five or more wires soldered to the via hole.

20. The method of claim 1 wherein the slot is angled or a spiral.
